(19) United States
(12) Patent Application Publication
(10) Pub. No.: US 2020/0105990 A1
(43) Pub. Date: Apr. 2, 2020

(54) SURFACE LIGHT SOURCE, METHOD FOR MANUFACTURING THE SAME, AND DISPLAY DEVICE USING THE SURFACE LIGHT SOURCE

(71) Applicant: Wuhan China Star Optoelectronics Technology Co.,Ltd., Wuhan (CN)

(72) Inventor: Yong YANG, Wuhan (CN)

(73) Assignee: Wuhan China Star Optoelectronics Technology Co., Ltd., Wuhan (CN)

(21) Appl. No.: 16/309,458

(22) PCT Filed: Nov. 23, 2018
(86) PCT No.: PCT/CN2018/117313

§ 371 Date: Dec. 13, 2018

(30) Foreign Application Priority Data
Sep. 27, 2018 (CN) 201811130283.6

(51) Int. Cl. H01L 33/64; H01L 33/60; H01L 33/62; H01L 25/075; G02F 1/1335

(52) U.S. Cl. CPC H01L 33/641; H01L 33/60; H01L 33/62; H01L 25/0753; H01L 2933/0075; H01L 2933/0033; H01L 2933/0058; H01L 2933/0066; G02F 1/133603

(57) ABSTRACT

The present invention provides a surface light source, a method for manufacturing the same, and a display device using the surface light source. The surface light source includes a substrate, a conductor line layer having a plurality of conductor lines to be distributed on one surface of the substrate, a mirror reflecting layer being covered on the conductor line layer, a high temperature resistant layer being covered on the mirror reflecting layer, a plurality of LED chips being arranged on the high temperature resistant layer and being electrically connected to the corresponding conductor lines, and a fluorescent film being covered on the LED chips and the high temperature resistant layer. The present invention can more effectively improve the reflectance and overall luminous efficiency of the surface light source.

### BACKGROUND OF THE INVENTION

### 1. Field of the Invention

The present invention relates to a flexible display device technology field, and more particularly to a surface light source, a method for manufacturing the same, and a display device using the surface light source.

### 2. Description of the Prior Art

With the development of science and technology, people have more and more frequent contacts with electronic equipment, and the requirements for display devices (or named display panels) thereof are also increasing. A mini LED display device is a powerful competitive product of the OLED display device in the future market. The mini LED display device has many advantages, such as bright, flexible and bendable, high dynamic contrast display technology, narrow frame display technology, abnormal display technology and so on. Thus the mini LED display device has become a hot spot of market research.

However, at present, there are still some gaps between the mini LED display device and the OLED display device using the conventional backlight in luminous efficiency, mixing uniformity, cost, module thickness and so on. In terms of luminous efficiency, the mini LED display device uses an FPC (Flexible Printed Circuit) or a PCB (Printed Circuit Board) as a substrate of a surface light source of a direct-type backlight module, and a white oil ink layer with high reflectivity is adopted on the substrate surface to reflect the internal reflection of the mini LED display device into a diffusion layer and a brighten film. On the market, because the reflectance of the existing white oil ink layer is difficult to exceed 85%, and the organic materials made into the white oil ink layer have higher absorbance for light, these conditions will result in more loss of the internal luminous efficiency of the surface light source. It can be seen that there is a technical bottleneck to enhance the light efficiency of the surface light source through improving the ink reflectivity.

### BRIEF SUMMARY OF THE INVENTION

The technical problem to be solved in the present invention is to providing a surface light source, a method for manufacturing the same, and display device using the surface light source, wherein the surface light source employs a mirror reflecting layer with a high temperature resistant layer to replace a white oil reflecting layer for effectively improving the reflectivity and the overall luminous efficiency of the surface light source.

In order to solve the above technical problems, the present invention provides a surface light source, which comprises: a substrate; a conductor line layer, having a plurality of conductor lines distributed on one surface of the substrate; a mirror reflecting layer, being covered on the conductor line layer; a high temperature resistant layer, being covered on the mirror reflecting layer; a plurality of LED chips, being arranged on the high temperature resistant layer and being electrically connected to the corresponding conductor lines; and a fluorescent film, being covered on the LED chips and the high temperature resistant layer.

In one embodiment of the present invention, a heat resistance temperature of the high temperature resistant layer is 200° C.-500° C., a penetration rate thereof is higher than 90%, and a thickness thereof is 100 μm-150 μm.

In one embodiment of the present invention, the high temperature resistant layer is made of one of polycarbonate copolymers, polyaryl ether ketone derivatives, polyimide sulfone derivatives, polyimide derivatives and aromatic polyheterocyclic derivatives.

In one embodiment of the present invention, a thickness of the mirror reflecting layer is 1 μm-5 μm, and a surface roughness of the mirror reflecting layer is 0.1 μm-0.3 μm.

In one embodiment of the present invention, the surface light source is further etched with a number of through holes, each of which passes through the high temperature resistant layer and the mirror reflecting layer; the conductor line layer are provided with a plurality of weld pads connected to the conductor lines; the through holes are corresponding to the weld pads; and each LED chip has pins, which pass through the corresponding through holes to be welded onto the corresponding weld pads.

The present invention also provides a method for manufacturing a surface light source, comprising the following steps: providing a flexible substrate; distributing a plurality of conductor lines on one surface of the flexible substrate to form a conductor line layer; forming a mirror reflecting layer by sputtering on the surface of the flexible substrate having the conductor lines; attaching a high temperature resistant layer 104 on the mirror reflecting layer by glue; disposing a plurality of LED chips on the high temperature resistant layer; wherein each LED chip is electrically connected to the corresponding conductor lines of the conductor line layer; and forming a fluorescent film on the high temperature resistant layer and the LED chips by hot pressing.

In one embodiment of the present invention, before disposing a plurality of LED chips on the high temperature resistant layer, the method further comprising the following steps: etching a number of through holes penetrated through the high temperature resistant layer and the mirror reflecting layer; wherein the conductor line layer are provided with a plurality of weld pads connected to the conductor lines; the through holes are corresponding to the weld pads; in the step of disposing the LED chips on the high temperature resistant layer, each LED chip has pins, which pass through the corresponding through holes to be welded onto the corresponding weld pads by a solder paste process, a crystal solidification process and a reflow soldering process.

In one embodiment of the present invention, the reflow soldering process is a laser reflow soldering process.

In one embodiment of the present invention, in the step of forming the fluorescent film on the high temperature resistant layer and the LED chips by hot pressing, a hot-pressing temperature is 130° C.-150° C., and a hot-pressing time is 10 min-15 min; after forming the fluorescent film on the high temperature resistant layer and the LED chips by hot pressing, a semi-finished product of the surface light source is obtained, and then the semi-finished product is roasted for 2 min-10 min at 130° C.-150° C. and becomes a finished product of the surface light source.

The present invention further provides a display device comprising a surface light source.

The surface light source and the display device using the surface light source of the present invention employ the mirror reflecting layer with the high temperature resistant layer to replace a white oil reflecting layer on the market. The reflectivity of the mirror reflecting layer with the high temperature resistant layer reaches over 90%, which is higher than the reflectivity of the best white oil reflecting layer on the market now 85%. The reflection spectrum of the mirror reflecting layer with the high temperature resistant layer is higher in the blue band, and the blue light has higher luminous efficiency and excitation energy, so this will more effectively improve the reflectance and overall luminous efficiency of the surface light source. Moreover, in the method for manufacturing the surface light source, the laser reflow soldering process is adopted to effectively avoid the shrinkage of the substrate and each film. The high temperature resistant layer and the mirror reflecting layer with high temperature resistance are not affected by the high temperature process during hot-pressing coating. Further, the mirror reflecting layer with the high temperature resistant layer is not affected by the high temperature process when hot pressing. The method for manufacturing the surface light source is more simple and reasonable, and is conducive to control, thus further improving the overall quality of the surface light source.

### BRIEF DESCRIPTION OF THE DRAWINGS

For more clearly understanding above content of the present invention, the following text will briefly introduce the accompanying drawings used in the preferred embodiment of the present invention. It is obvious that the accompanying drawings in the following description are only some embodiments of the present invention. For the technical personnel of the field, other drawings can also be obtained from these drawings without paying creative work.

The present invention is further explained in conjunction with the accompanying drawings and embodiments.

FIG. 1 is a layered structure schematic view of a surface light source of one embodiment of the invention;

FIG. 2 is a distribution diagram of a conductor line layer of FIG. 1 and mainly shows the distribution of conductor lines and the positions of weld pads;

FIG. 3 is a reflectivity comparison diagram of a mirror reflecting layer with a high temperature resistant layer in one embodiment of the invention and a white oil reflecting layer;

FIG. 4 is a flow chart of a method for manufacturing the surface light source of one embodiment of the invention; and

FIG. 5 is a layered structure schematic view of a display device of one embodiment of the invention.

### DETAILED DESCRIPTION OF THE PREFERRED EMBODIMENTS

The following text will describe embodiments of the present invention in detailed. The embodiments are shown in the accompanying drawings, in which the same or similar signs represent the same or similar elements or elements with the same or similar functions from beginning to end. The following embodiments described with reference to the accompanying drawings are illustrative and are intended only to explain the present invention and are not understood as limitations to the invention.

The following description of every embodiment with reference to the accompanying drawings is used to exemplify a specific embodiment, which may be carried out in the present invention. Directional terms mentioned in the present invention, such as “up”, “down”, “front”, “back”, “left”, “right”, “top”, “bottom” etc., are only used with reference to the orientation of the accompanying drawings. Therefore, the used directional terms are intended to illustrate, but not to limit, the present invention.

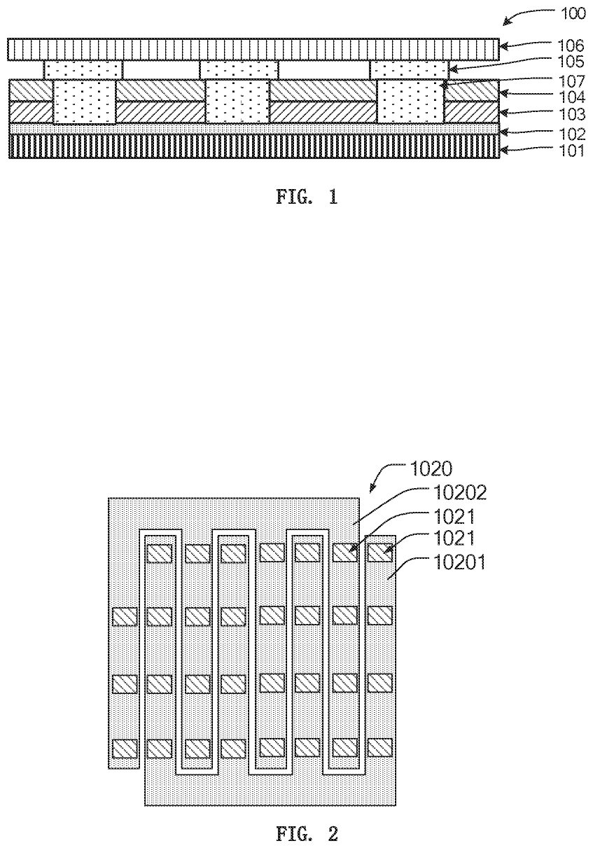

Referring to FIG. 1, in one embodiment, a surface light source 100 of the present invention includes a substrate 101, a conductor line layer 102, a mirror reflecting layer 103, a high temperature resistant layer 104, a plurality of LED chips 105, and a fluorescent film 106.

The substrate 101 may be an FPC substrate or a PCB substrate. In the embodiment, the substrate 101 is the FPC substrate, which can be named a flexible substrate.

The conductor line layer 102 has a plurality of conductor lines 1020 (seen in FIG. 2). The conductor lines 1020 are distributed on an upper surface of the substrate 101 to form the conductor line layer 102. The conductor lines 1020 can be made of copper conductors, which are attached to the upper surface of the flexible substrate 101 to form a basic structure of the surface light source 100.

Referring to FIG. 2, according to the design requirements of the process, each LED chip 105 has pins, including a P-pole pin and an N-pole pin. The conductor lines 1020 include a P-pole conductor line 10201 and an N-pole conductor line 10202, both of which are provided with a plurality of weld pads 1021.

The mirror reflecting layer 103 is covered on the conductor line layer 102. In the embodiment, the mirror reflecting layer 103 covers the basic structure of the surface light source 100. Namely, the mirror reflecting layer 103 covers an entire surface of the copper conductors. A thickness of the mirror reflecting layer 103 is 1 μm-5 μm, preferably 3 μm. A surface roughness of the mirror reflecting layer 103 is 0.1 μm-0.3 μm, and its average surface roughness is generally 0.2 μm. The surface roughness of the mirror reflecting layer 103 can increase the diffuse reflection of light to a certain extent, so that the light can disperse evenly.

The high temperature resistant layer 104 is covered on the mirror reflecting layer 103. In the embodiment, because the high temperature resistant layer 104 is added on the mirror reflecting layer 103, it can protect the mirror reflecting layer 103 from being damaged when the fluorescent film 106 is subsequently hot-pressed. According to the design requirements of the performance, the high temperature resistant layer 104 is made of one of polycarbonate copolymers, polyaryl ether ketone derivatives, polyimide sulfone derivatives, polyimide derivatives and aromatic polyheterocyclic derivatives. Wherein, a heat resistance temperature of the high temperature resistant layer 104 is 200° C.-500° C., its penetration rate is higher than 90%, and its thickness is 100 μm-150 μm, preferably 120 μm-130 μm.

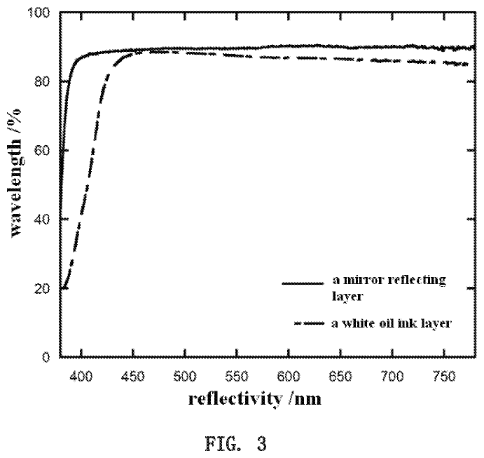

Referring to FIG. 3, FIG. 3 is a reflectivity comparison diagram of the mirror reflecting layer with the high temperature resistant layer of the embodiment and a white oil reflecting layer. It can be seen from the reflectivity comparison diagram of FIG. 3 that a reflectivity of the mirror reflecting layer 103 with the high temperature resistant layer 104 is over 90%, which is higher than the reflectivity of the best white oil reflecting layer on the market now 85%. A reflectivity of the mirror reflecting layer 103 with the high temperature resistant layer 104 is higher in a blue band, and a blue light has higher luminous efficiency and excitation energy, so this will more effectively improve the luminous efficiency.

Please refer to FIG. 1, the LED chips 105 are arranged on the high temperature resistant layer 104 and are electrically connected to the conductor lines 1020 (seen in FIG. 2). The length and width of each LED chip 105 are 100 μm-500 μm.

In die bonding, the surface light source 100 is further etched with a number of through holes 107, each of which passes through the high temperature resistant layer 104 and the mirror reflecting layer 103. The through holes 107 are corresponding to the weld pads 1021. The pins of each LED chip pass through the corresponding through holes 107 to be welded onto the corresponding weld pads 1021.

The fluorescent film 106 is covered on the LED chips 105 and the high temperature resistant layer 104.

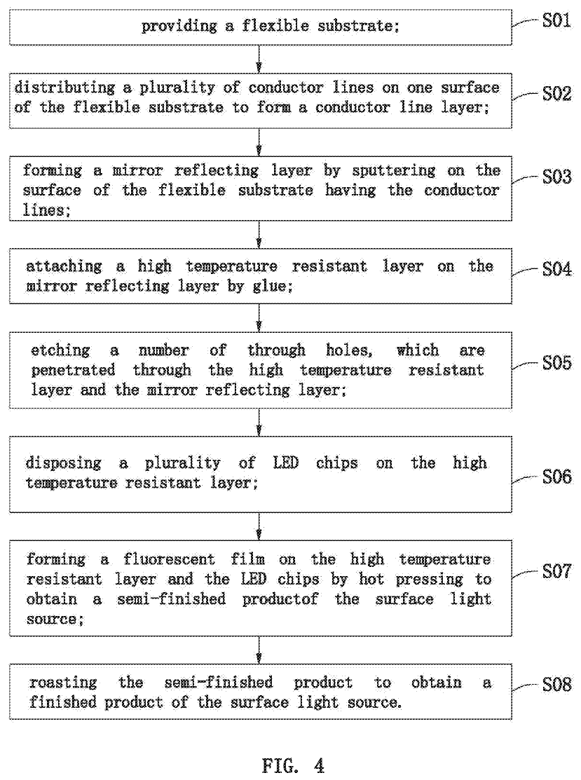

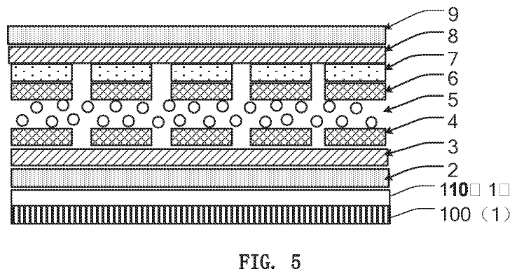

Referring to FIG. 4, in order to fully realize the surface light source 100 of the above embodiment, the present invention further provides a method for manufacturing the surface light source 100, including steps S01-S08.

The structures and the reference numerals involved below can refer to FIG. 1 and FIG. 2.

A step S01 is providing a substrate 101, which may be an FPC substrate or a PCB substrate.

A step S02 is distributing a plurality of conductor lines 1020 on an upper surface of the substrate 101 to form a conductor line layer 102. The conductor lines 1020 can be made of copper conductors, which are attached to the upper surface of the substrate 101 to form a basic structure of the surface light source 100.

A step S03 is forming a mirror reflecting layer 103 by sputtering on the upper surface of the substrate 101 having the conductor lines 1020. The mirror reflecting layer 103 covers the basic structure of the surface light source 100 and an entire surface of the copper conductors. A thickness of the mirror reflecting layer 103 is 1 μm-5 μm, preferably 3 μm. A surface roughness of the mirror reflecting layer 103 is 0.1 μm-0.3 μm, and its average surface roughness is generally 0.2 μm.

A step S04 is attaching a high temperature resistant layer 104 on the mirror reflecting layer 103. Wherein, a heat resistance temperature of the high temperature resistant layer 104 is 200° C.-500° C., its penetration rate is higher than 90%, and its thickness is 100 μm-150 μm, preferably 120 μm-130 μm. Specifically, the high temperature resistant layer 104 is glued on the mirror reflecting layer 103 by glue, so the high temperature resistant layer 104 can be closely bonded with the mirror reflecting layer 103.

A step S05 is etching a number of through holes 107, which are penetrated through the high temperature resistant layer 104 and the mirror reflecting layer 103. The conductor line layer 102 has a plurality of weld pads 1021 connected to the conductor lines 1020. In the embodiment, each LED chip 105 has pins, including a P-pole pin and an N-pole pin. The conductor lines 1020 are divided into a P-pole conductor line and an N-pole conductor line, both of which are provided with the weld pads 1021. The through holes 107 are corresponding to the weld pads 1021. When etching is completed, the weld pads 1021 can be exposed in the through holes 107. This will facilitate subsequent operations.

A step S06 is disposing a plurality of LED chips 105 on the high temperature resistant layer 104. Each LED chip 105 is electrically connected to the corresponding conductor lines of the conductor line layer 102. Specifically, the pins of the LED chips 105 pass through the corresponding through holes 107 to be welded onto the corresponding weld pads 1021 by a solder paste process, a crystal solidification process and a reflow soldering process. For example, solder pastes can be coated on the weld pads 1021 by the solder paste process, and then the LED chips 105 can be fixed by the solidification process and the reflow soldering process. The reflow soldering process is a laser reflow soldering process. In the embodiment, each LED chip 105 is welded by the laser reflow soldering process. The laser reflow soldering process is different from a conventional hot gas reflow soldering process. When the conventional hot gas reflow soldering process is carried out, the welding area is large. But when the laser reflow soldering process is used, laser beams can be concentrated in the weld pads 1021, and form a local heating zone on the weld pads 1021 in a relatively short time, thus avoiding the expansion and contraction of the substrate or each layer caused by the conventional hot gas reflow soldering process.

A step S07 is forming a fluorescent film 106 on the high temperature resistant layer 104 and the LED chips 105 by hot pressing. A hot-pressing temperature is 130° C.-150° C., a hot-pressing time is 10 min-15 min (10 to 15 minutes). Wherein, the hot-pressing temperature is 130° C.-150° C., but a heat resistance temperature of the high temperature resistant layer 104 is 200° C.-500° C., so the hot-pressing temperature is much lower than the heat resistance temperature of the high temperature resistant layer 104, thereby effectively protecting the mirror reflecting layer 103 from the influence of the hot-pressing temperature. In the embodiment, the fluorescent film 106 is hot pressed on the high temperature resistant layer 104 and the LED chips 105, so a semi-finished product of the surface light source 100 is obtained.

A step S08 is putting the semi-finished product of the surface light source 100 into an oven and roasting for 2 min-10 min at 130° C.-150° C. to solidify the fluorescent film 106 and obtain a finished product of the surface light source 100.

The following text will take a mini LED display device as an example to introduce the structure of the display device of the present invention.

Referring to FIG. 5, in one embodiment, the mini LED display device includes a backlight device 1, a first polarizer 2, a first glass substrate 3, a first electrode layer 4, a liquid crystal molecular layer 5, a second electrode layer 6, a color filter 7, a second glass substrate 8 and a second polarizer 9. Wherein the first polarizer 2 and the second polarizer 9 are opposite to each other, and located on the backlight device 1. The first glass substrate 3 and the second glass substrate 8 are opposite to each other, and located between the first polarizer 2 and the second polarizer 9. The first electrode layer 4 and the second electrode layer 6 are disposed between the first glass substrate 3 and the second glass substrate 8. The liquid crystal molecular layer 5 is disposed between the first electrode layer 4 and the second electrode layer 6. And the color filter 7 is disposed between the second glass substrate 8 and the second electrode layer 6. The light emitted by the backlight device 1 passes through the first polarizer 2, the first glass substrate 3, the liquid crystal molecular layer 5, the color filter 7, the second glass substrate 8 and the second polarizer 9 in sequence.

The backlight device 1 includes the surface light source 100 and at least one optical film 110. The optical film 110 may be a diffusion sheet, a prism sheet, an intensifying film or a combination, disposed on the surface light source 100.

Since the focus of the present invention is on the surface light source 100 in the backlight device 1 of the mini LED display device, other components of the mini LED display device will not be described in detail.

Of course, the backlight device 1 of the embodiment can also be applied to other kinds of display devices. The mini LED display device listed in the embodiment is merely an explanation of the invention, but not a limitation thereof.

The above description is only a preferred embodiment of the invention and is not intended to limit the invention. Any modification, equivalent substitution and improvement made within the spirit and principles of the invention shall be included in the scope of protection of the invention.

### REFERENCE NUMERALS

1 backlight device
100 surface light source
110 optical film
101 flexible substrate
102 conductor line layer
103 mirror reflecting layer
104 high temperature resistant layer
105 LED chip
106 fluorescent film
107 through hole
1020 conductor line
1021 weld pad
10201 P-pole conductor line
10202 N-pole conductor line
2 first polarizer
3 first glass substrate
4 first electrode layer
5 liquid crystal molecular layer
6 second electrode layer
7 color filter
8 second glass substrate
9 second polarizer

What is claimed is:

1. A surface light source, which comprises:
a substrate;
a conductor line layer, having a plurality of conductor lines distributed on one surface of the substrate;
a mirror reflecting layer, being covered on the conductor line layer;
a high temperature resistant layer, being covered on the mirror reflecting layer;
a plurality of LED chips, being arranged on the high temperature resistant layer and being electrically connected to the corresponding conductor lines; and
a fluorescent film, being covered on the LED chips and the high temperature resistant layer.

2. The surface light source as claimed in claim 1, wherein a heat resistance temperature of the high temperature resistant layer is 200° C.-500° C., a penetration rate thereof is higher than 90%, and a thickness thereof is 100 μm-150 μm.

3. The surface light source as claimed in claim 1, wherein the high temperature resistant layer is made of one of polycarbonate copolymers, polyaryl ether ketone derivatives, polyimide sulfone derivatives, polyimide derivatives and aromatic polyheterocyclic derivatives.

4. The surface light source as claimed in claim 1, wherein a thickness of the mirror reflecting layer is 1 μm-5 μm, and a surface roughness of the mirror reflecting layer is 0.1 μm-0.3 μm.

5. The surface light source as claimed in claim 1, wherein the surface light source is further etched with a number of through holes, each of which passes through the high temperature resistant layer and the mirror reflecting layer; the conductor line layer are provided with a plurality of weld pads connected to the conductor lines; the through holes are corresponding to the weld pads; and each LED chip has pins, which pass through the corresponding through holes to be welded onto the corresponding weld pads.

6. A method for manufacturing a surface light source as claimed in claim 1, comprising the following steps:
providing a flexible substrate;
distributing a plurality of conductor lines on one surface of the flexible substrate to form a conductor line layer;
forming a mirror reflecting layer by sputtering on the surface of the flexible substrate having the conductor lines;
attaching a high temperature resistant layer 104 on the mirror reflecting layer by glue;
disposing a plurality of LED chips on the high temperature resistant layer;
wherein each LED chip is electrically connected to the corresponding conductor lines of the conductor line layer; and
forming a fluorescent film on the high temperature resistant layer and the LED chips by hot pressing.

7. The method for manufacturing the surface light source as claimed in claim 6, wherein before disposing a plurality of LED chips on the high temperature resistant layer, the method further comprising the following steps:
etching a number of through holes penetrated through the high temperature resistant layer and the mirror reflecting layer; wherein the conductor line layer are provided with a plurality of weld pads connected to the conductor lines; the through holes are corresponding to the weld pads;
in the step of disposing the LED chips on the high temperature resistant layer, each LED chip has pins, which pass through the corresponding through holes to be welded onto the corresponding weld pads by a solder paste process, a crystal solidification process and a reflow soldering process.

8. The method for manufacturing the surface light source as claimed in claim 7, wherein the reflow soldering process is a laser reflow soldering process.

9. The method for manufacturing the surface light source as claimed in claim 6, wherein in the step of forming the fluorescent film on the high temperature resistant layer and the LED chips by hot pressing, a hot-pressing temperature is 130° C.-150° C., and a hot-pressing time is 10 min-15 min;
after forming the fluorescent film on the high temperature resistant layer and the LED chips by hot pressing, a semi-finished product of the surface light source is obtained, and then the semi-finished product is roasted for 2 min-10 min at 130° C.-150° C. and becomes a finished product of the surface light source.

10. A display device, comprising a surface light source as claimed in claim 1.
